(19) United States
(12) Patent Application Publication
(10) Pub. No.: US 2026/0005157 A1
(43) Pub. Date: Jan. 1, 2026

(54) ELECTRONIC DEVICE

(71) Applicant: Rohm Co., Ltd., Kyoto-shi (JP)

(72) Inventor: Hiroki MIYAZAKI, Kyoto-shi (JP)

(21) Appl. No.: 19/319,981

(22) Filed: Sep. 5, 2025

Related U.S. Application Data
(63) Continuation of application No. PCT/JP2024/007386, filed on Feb. 28, 2024.

(30) Foreign Application Priority Data
Mar. 13, 2023 (JP) 2023-038754

(51) Int. Cl. H01L 23/552; H01L 23/00; H01L 23/538; H01L 25/065; H01L 25/16

(52) U.S. Cl. CPC H01L 23/552; H01L 23/5384; H01L 24/16; H01L 25/0655; H01L 25/16; H01L 2224/16227; H01L 2224/16238

(57) ABSTRACT

An electronic device comprises a first electronic component, a support member including a support surface supporting the first electronic component, a columnar conductor disposed in a direction where the support surface faces with respect to the support member, and a sealing resin formed on the support surface and covering the first electronic component. The columnar conductor includes a conductor top surface facing the same side as the support surface in a thickness direction of the support member. The conductor top surface is covered with the sealing resin.

### TECHNICAL FIELD

The present disclosure relates to an electronic device.

### BACKGROUND ART

Conventionally, an electronic device comprising a plurality of electronic components has been known. One example of such an electronic device is disclosed in JP-A-2021-34600, for example. The electronic device (semiconductor device) disclosed in the document includes a semiconductor element, a plurality of electronic components, an insulating layer and a sealing resin. The semiconductor element is an LSI. Each of the electronic components is either a diode or a passive element such as a resistor, capacitor or inductor. The insulating layer supports the semiconductor element and the electronic components. The sealing resin is formed on the insulating layer. The sealing resin covers the semiconductor element and the electronic components.

### BRIEF DESCRIPTION OF THE DRAWINGS

FIG. 1 is a plan view of an electronic device according to a first embodiment.

FIG. 2 is a plan view of FIG. 1, in which the sealing resin is indicated by imaginary lines.

FIG. 3 is a plan view of FIG. 2, in which the sealing resin and the columnar conductor are omitted and the first electronic component and the second electronic component are indicated by imaginary lines.

FIG. 4 is a front view of the electronic device according to the first embodiment.

FIG. 5 is a bottom view of the electronic device according to the first embodiment.

FIG. 6 is a left-side view of the electronic device according to the first embodiment.

FIG. 7 is a cross-sectional view taken along line VII-VII of FIG. 2.

FIG. 8 is a partially enlarged view of FIG. 2.

FIG. 9 is a cross-sectional view corresponding to FIG. 7, illustrating a step of a method of manufacturing the electronic device according to the first embodiment.

FIG. 10 is a cross-sectional view corresponding to FIG. 7, illustrating a step of a method of manufacturing the electronic device according to the first embodiment.

FIG. 11 is a cross-sectional view corresponding to FIG. 7, illustrating a step of a method of manufacturing the electronic device according to the first embodiment.

FIG. 12 is a cross-sectional view corresponding to FIG. 7, illustrating a step of a method of manufacturing the electronic device according to the first embodiment.

FIG. 13 is a cross-sectional view corresponding to FIG. 7, illustrating a step of a method of manufacturing the electronic device according to the first embodiment.

FIG. 14 is a cross-sectional view corresponding to FIG. 7, illustrating a step of a method of manufacturing the electronic device according to the first embodiment.

FIG. 15 is a cross-sectional view corresponding to FIG. 7, illustrating a step of a method of manufacturing the electronic device according to the first embodiment.

FIG. 16 is a cross-sectional view corresponding to FIG. 7, illustrating a step of a method of manufacturing the electronic device according to the first embodiment.

FIG. 17 is a cross-sectional view corresponding to FIG. 7, illustrating a step of a method of manufacturing the electronic device according to the first embodiment.

FIG. 18 is a cross-sectional view corresponding to FIG. 7, illustrating a step of a method of manufacturing the electronic device according to the first embodiment.

FIG. 19 is an enlarged plan view illustrating a relevant part of an electronic device according to a first variation of the first embodiment.

FIG. 20 is an enlarged plan view illustrating a relevant part of an electronic device according to a second variation of the first embodiment.

FIG. 21 is a bottom view of an electronic device according to a third variation of the first embodiment.

FIG. 22 is a cross-sectional view taken along line XXII-XXII of FIG. 21.

FIG. 23 is a plan view of an electronic device according to a second embodiment, in which the sealing resin is indicated by imaginary lines.

FIG. 24 is a plan view of an electronic device according to a variation of the second embodiment, in which the sealing resin is indicated by imaginary lines.

FIG. 25 is a plan view of an electronic device according to a third embodiment, in which the sealing resin is indicated by imaginary lines.

FIG. 26 is a cross-sectional view taken along line XXVI-XXVI of FIG. 25.

FIG. 27 is a plan view of an electronic device according to a variation of the third embodiment, in which the sealing resin is indicated by imaginary lines.

FIG. 28 is a plan view of an electronic device according to another embodiment, in which the sealing resin is indicated by imaginary lines.

FIG. 29 is a cross-sectional view taken along line XXIX-XXIX of FIG. 28.

### DETAILED DESCRIPTION OF EMBODIMENTS

The following describes preferred embodiments of the present disclosure in detail with reference to the drawings. In the following, identical or similar elements are denoted by the same reference signs, and redundant explanations are omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the expression “An object A (or the material thereof) contains a material C” includes “the object A (or the material thereof) is made of a material C” and “the object A (or the material thereof) is mainly composed of a material C”. Also, the expression “A surface A faces (one side or another side in) a direction B” implies the situation where, unless otherwise specifically noted, the surface A is oriented at 90 degrees with respect to the direction B, and the surface A is inclined with respect to the direction B.

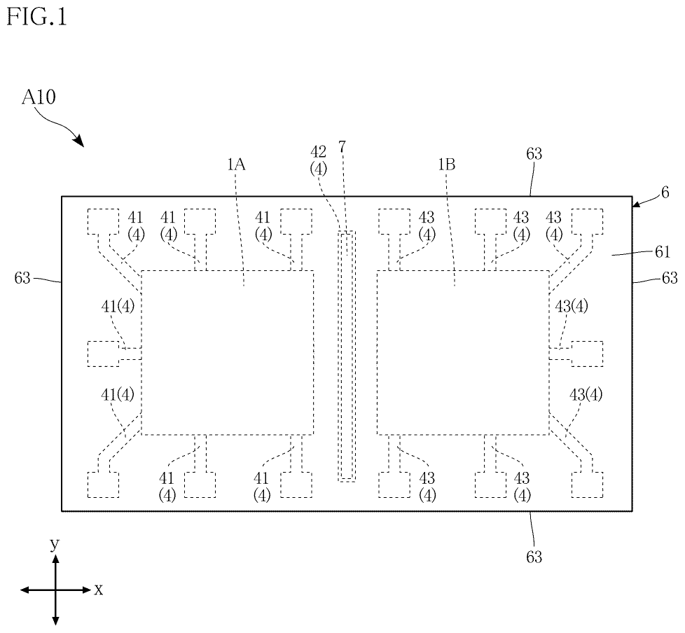

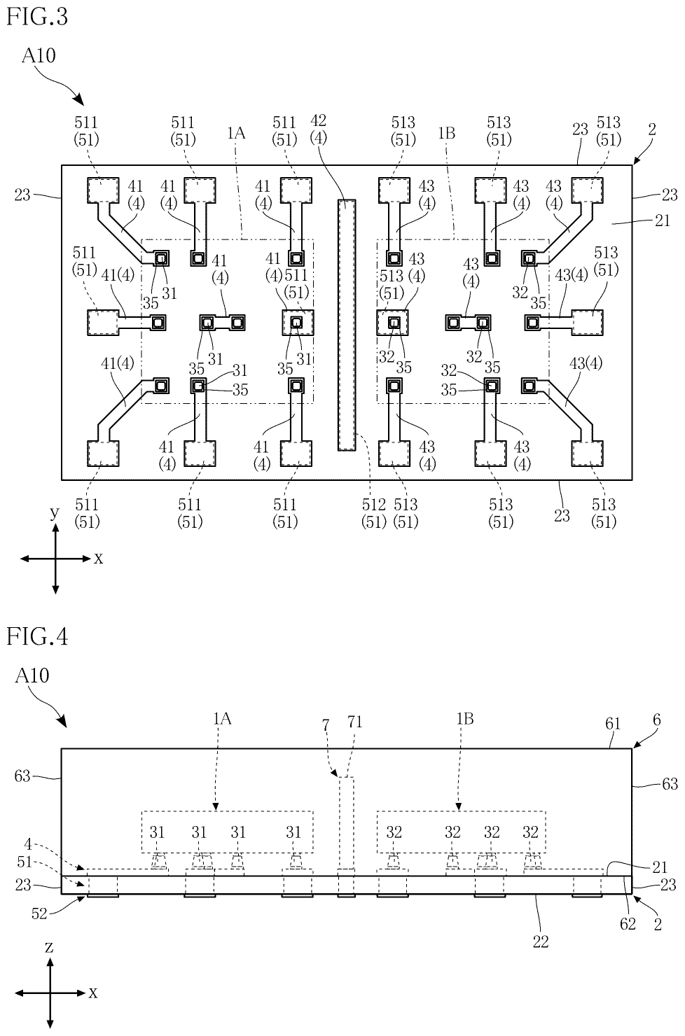

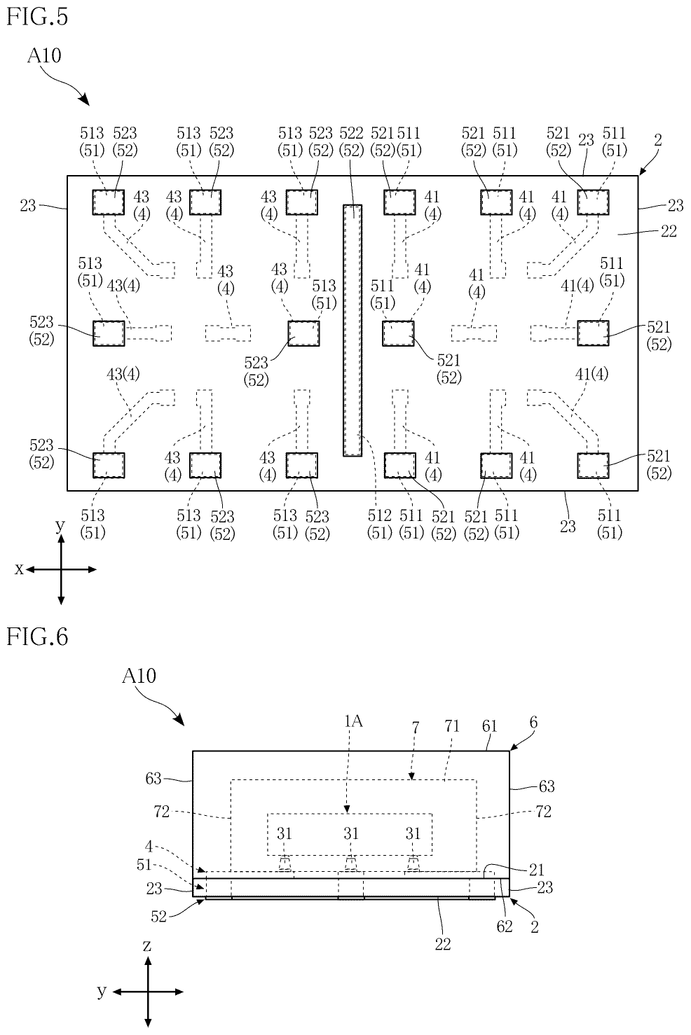

FIGS. 1 to 8 show an electronic device A10 according to a first embodiment. The electronic device A10 includes a first electronic component 1A, a second electronic component 1B, a support member 2, a plurality of bonding portions 31 and 32, a wiring layer 4, a through conductor 51, a terminal 52, a sealing resin 6, and a columnar conductor 7. The electronic device A10 is surface-mounted on a wiring board of an electronic apparatus or an electric vehicle. The electronic device A10 is in a form of a leadless package type, and in particular, a QFN (Quad Flat Non-leaded) package type. The electronic device A10 has a rectangular shape in plan view.

For convenience of explanation, reference is made to a thickness direction z, a first direction x and a second direction y, which are orthogonal to each other. For example, the thickness direction z is one example of a thickness direction of the electronic device A10. In the following description, one side in the thickness direction z may be referred to as upper, and the other side as lower. Note that the terms such as “upward”, “downward”, “upper”, “lower”, “upper surface” and “lower surface” indicate the relative positional relationship of each component in the thickness direction z, and do not necessarily define the relationship with respect to the direction of gravity. The term “plan view” means as viewed in the thickness direction z.

The first electronic component 1A and the second electronic component 1B each play a functionally central role of the electronic device A10. Each of the first electronic component 1A and the second electronic component 1B may be an integrated circuit such as an LSI. Alternatively, each of the first electronic component 1A and the second electronic component 1B may be a voltage control element such as an LDO (Low Drop Out) regulator, an amplification element such as an operational amplifier, or a discrete element such as a transistor or diode. Each of the first electronic component 1A and the second electronic component 1B has a rectangular shape in plan view. Each of the first electronic component 1A and the second electronic component 1B is supported by the support member 2. Each of the first electronic component 1A and the second electronic component 1B overlaps with the support member 2 in plan view.

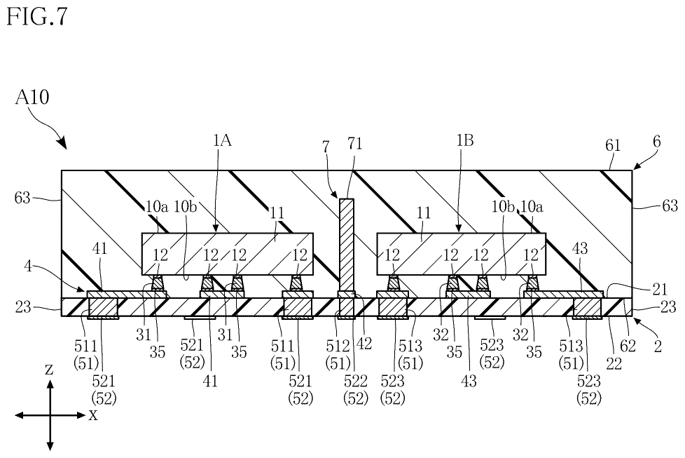

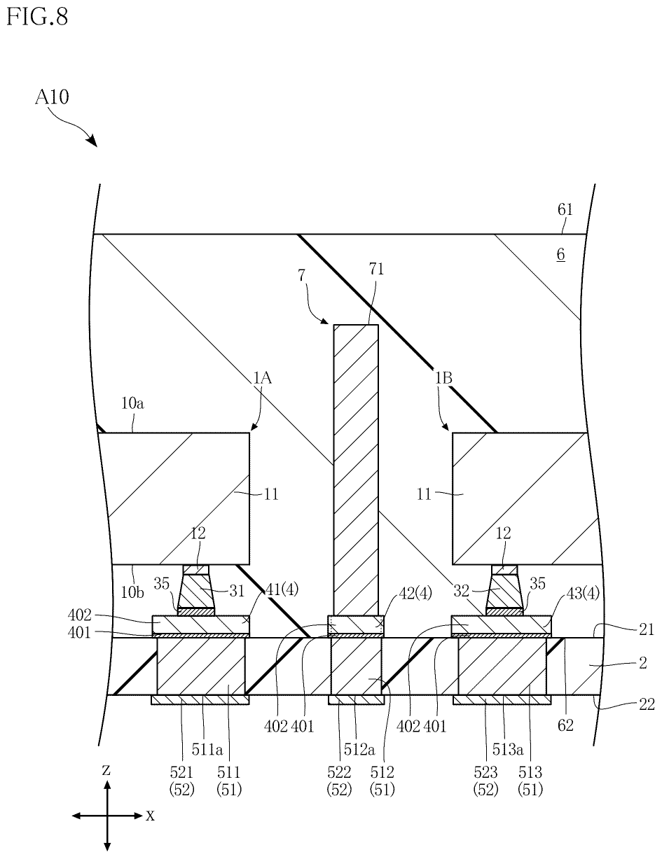

As shown in FIGS. 7 and 8, each of the first electronic component 1A and the second electronic component 1B includes an element top surface 10a and an opposing surface 10b. The element top surface 10a and the opposing surface 10b are spaced apart from each other in the thickness direction z. The element top surface 10a and the opposing surface 10b face away from each other. The element top surface 10a is covered with the sealing resin 6. The opposing surface 10b faces the support member 2 and the wiring layer 4.

As shown in FIGS. 7 and 8, each of the first electronic component 1A and the second electronic component 1B includes a body portion 11 and a plurality of electrode pads 12. In the case where the first electronic component 1A and the second electronic component 1B are LSIs, the body portion 11 contains a semiconductor material. Each of the electrode pads 12 is electrically connected to a circuit (not shown) formed in the body portion 11. The opposing surface 10b corresponds to a lower surface (a surface facing downward in the thickness direction z) of the body portion 11. In the example shown in FIGS. 7 and 8, each electrode pad 12 projects downwardly in the thickness direction z from the opposing surface 10b. However, each electrode pad 12 may be flush with the opposing surface 10b, or may be recessed upwardly in the thickness direction z from the opposing surface 10b. The opposing surface 10b is partially covered with an insulating film (not shown), and each electrode pad 12 is exposed from the insulating film. The insulating film contains, for example, polyimide or polybenzoxazole. Each electrode pad 12 contains metal, such as aluminum, silver, gold, or copper. Each electrode pad 12 may have a single-layer structure or a multilayer stacked structure.

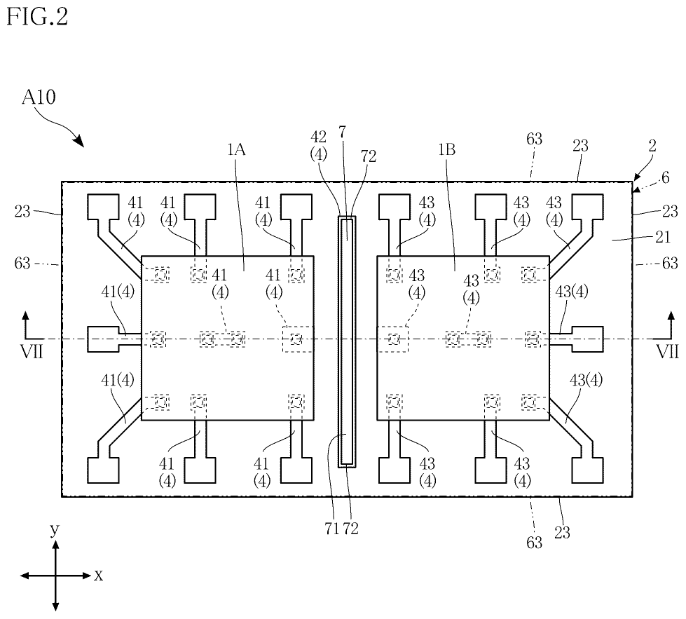

As shown in FIGS. 2, 4, and 6 to 8, the support member 2 supports the first electronic component 1A and the second electronic component 1B. The support member 2 contains, for example, a resin material. The resin material may be identical to or different from that of the sealing resin 6. The support member 2 may contain the resin material containing a filler such as silica. Alternatively, the support member 2 may contain a material other than a resin, such as an intrinsic single-crystal semiconductor (e.g., silicon (Si)), glass, or ceramic. As shown in FIGS. 2, 3, and 5, the support member 2 has a rectangular shape in plan view. The thickness (dimension along the thickness direction z) of the support member 2 is not particularly limited, and is in a range from 30 μm to 300 μm, for example. The support member 2 includes a support surface 21, a reverse surface 22, and a plurality of side surfaces 23.

As shown in FIGS. 4 and 6 to 8, the support surface 21 and the reverse surface 22 are spaced apart from each other in the thickness direction z. The support surface 21 and the reverse surface 22 face away from each other. The support surface 21 is the upper surface of the support member 2, and the reverse surface 22 is the lower surface of the support member 2. The support surface 21 faces (the opposing surfaces 10b of) the first electronic component 1A and the second electronic component 1B. The reverse surface 22 faces a circuit board when the electronic device A10 is mounted on the circuit board. In the present embodiment, the support surface 21 is covered with the sealing resin 6, and the reverse surface 22 is exposed from the sealing resin 6. As shown in FIGS. 4 and 6 to 8, each of the side surfaces 23 is sandwiched between the support surface 21 and the reverse surface 22. Each side surface 23 has an upper end in the thickness direction z connected to the support surface 21, and a lower end in the thickness direction z connected to the reverse surface 22. Each side surface 23 is flat and orthogonal to the support surface 21 and the reverse surface 22. As shown in FIGS. 2 to 7, the side surfaces 23 include one facing one side in the first direction x, one facing another side in the first direction x, one facing one side in the second direction y, and one facing another side in the second direction y.

Each of the bonding portions 31 and 32 bonds the wiring layer 4 to either the first electronic component 1A or the second electronic component 1B. The wiring layer 4 is bonded to the first electronic component 1A through the bonding portions 31 and to the second electronic component 1B through the bonding portions 32. Each of the bonding portions 31 and 32 is a conductive bonding material. Each bonding portion 31 and 32 is, for example, solder. The solder includes an alloy containing tin (Sn) (e.g., a Sn—Ag (silver) alloy), and is used together with flux. The compositions of the bonding portions 31 and 32 are not limited to this example. Each bonding portion 31 and 32 may be a sintered metal or a conductive paste material instead of solder.

The bonding portions 31 are interposed between the respective electrode pads 12 of the first electronic component 1A and the wiring layer 4, and bonds them. Hence, the first electronic component 1A is electrically connected to the wiring layer 4 via the bonding portions 31.

The bonding portions 32 are interposed between the respective electrode pads 12 of the second electronic component 1B and the wiring layer 4, and bonds them. Hence, the second electronic component 1B is electrically connected to the wiring layer 4 via the bonding portions 32.

The wiring layer 4 is a conductor disposed within the electronic device A10. The wiring layer 4 electrically connects the first electronic component 1A and the second electronic component 1B to the terminal 52 together with the through conductor 51. The wiring layer 4 is interposed between the support member 2 and the sealing resin 6. The wiring layer 4 is formed on and in contact with the support surface 21 of the support member 2.

The wiring layer 4 includes a plurality of first wiring portions 41, a second wiring portion 42, and a plurality of third wiring portions 43. The first wiring portions 41, the second wiring portion 42, and the third wiring portions 43 are spaced apart from one another. Each of the first wiring portions 41 is electrically connected to the first electronic component 1A. The columnar conductor 7 is stood from the second wiring portion 42. Each of the third wiring portions 43 is electrically connected to the second electronic component 1B.

As shown in FIG. 8, the wiring layer 4 (each of the first wiring portions 41, the second wiring portion 42, and the third wiring portions 43) includes a seed layer 401 and a plating layer 402, for example. The seed layer 401 is formed on the support surface 21 and is in contact with the support member 2. The seed layer 401 contains, for example, titanium. The plating layer 402 is laminated on the seed layer 401. The plating layer 402 contains, for example, copper. Alternatively, the wiring layer 4 may be a single layer made of a conductive material. The thickness (dimension along the thickness direction z) of the wiring layer 4 is not particularly limited, and is, for example, in a range from 10 μm to 100 μm.

The through conductor 51 penetrates the support member 2 in the thickness direction z. The through conductor 51 is coupled to the wiring layer 4 and the terminal 52, and electrically connects the wiring layer 4 to the terminal 52. The through conductor 51 contains, for example, metal such as copper. The through conductor 51 includes a plurality of first conductor portions 511, a second conductor portion 512, and a plurality of third conductor portions 513. The first conductor portions 511, the second conductor portion 512, and the third conductor portions 513 are spaced apart from one another.

The first conductor portions 511 are connected to the respective first wiring portions 41. The planar shape of each first conductor portion 511 is not particularly limited, and in the illustrated example, it is rectangular. In the illustrated example, each first conductor portion 511 has an upper surface (i.e., a surface facing upward in the thickness direction z) that is flush with the support surface 21 of the support member 2. The upper surface of each first conductor portion 511 is in contact with the corresponding first wiring portion 41. In the present embodiment, all the first conductor portions 511 have side surfaces (facing the first direction x or the second direction y) that are covered with the support member 2. However, some of the side surfaces may alternatively be exposed from the support member 2.

Each of the first conductor portions 511 has a first end surface 511a. The first end surface 511a described below is, unless otherwise specifically noted, common among the first conductor portions 511. The first end surface 511a faces downward in the thickness direction z. The first end surface 511a faces away from the sealing resin 6 in the thickness direction z. The first end surface 511a is exposed from the reverse surface 22 of the support member 2. In an example shown in FIG. 8, the first end surface 511a is flush with the reverse surface 22.

The second conductor portion 512 is connected to the second wiring portion 42. The planar shape of the second conductor portion 512 is not particularly limited, and in the illustrated example, it is a band extending in the second direction y. In the illustrated example, the second conductor portion 512 has an upper surface (a surface facing upward in the thickness direction z) that is flush with the support surface 21 of the support member 2.

The upper surface of the second conductor portion 512 is in contact with the second wiring portion 42. The second conductor portion 512 is disposed between the first conductor portions 511 and the third conductor portions 513 in the second direction y.

The second conductor portion 512 includes a second end surface 512a. The second end surface 512a faces downward in the thickness direction z. The second end surface 512a faces away from the sealing resin 6 in the thickness direction z. The second end surface 512a is exposed from the reverse surface 22 of the support member 2. In an example shown in FIG. 8, the second end surface 512a is flush with the reverse surface 22.

The third conductor portions 513 are connected to the respective third wiring portions 43. The planar shape of each third conductor portion 513 is not particularly limited, and in the illustrated example, it is rectangular. In the illustrated example, each third conductor portion 513 has an upper surface (a surface facing upward in the thickness direction z) that is flush with the support surface 21 of the support member 2. The upper surface of each third conductor portion 513 is in contact with the corresponding third wiring portion 43. In the present embodiment, all the third conductor portions 513 have side surfaces (facing the first direction x or the second direction y) that are covered with the support member 2. However, some of the side surfaces may alternatively be exposed from the support member 2.

Each of the third conductor portions 513 has a third end surface 513a. The third end surface 513a described below is, unless otherwise specifically noted, common among the third conductor portions 513. The third end surface 513a faces downward in the thickness direction z. The third end surface 513a faces away from the sealing resin 6 in the thickness direction z. The third end surface 513a is exposed from the reverse surface 22 of the support member 2. In an example shown in FIG. 8, the third end surface 513a is flush with the reverse surface 22.

The terminal 52 is a conductor that is electrically connected to the wiring layer 4 and exposed outside the electronic device A10. The terminal 52 serves as a terminal for mounting the electronic device A10 on a circuit board. The terminal 52 is in contact with a portion of the through conductor 51 that is exposed from the reverse surface 22 of the support member 2. The terminal 52 is located below the support member 2 in the thickness direction z. The terminal 52 projects from the reverse surface 22. The terminal 52 is formed, for example, by electroless plating. The terminal 52 may include a plurality of metal layers of a Ni layer, a palladium (Pd) layer and a gold (Au) layer laminated in this order from the side in contact with the through conductor 51. Alternatively, the terminal 52 may include a plurality of metal layers of a Ni layer and an Au layer laminated in this order, or a Cu layer, an Ag layer, and a Sn layer laminated in this order, from the side in contact with the through conductor 51. The material and method of forming the terminal 52 are not limited to these examples. The terminal 52 includes a plurality of first terminal portions 521, a second terminal portion 522, and a plurality of third terminal portions 523. The first terminal portions 521, the second terminal portion 522, and the third terminal portions 523 are spaced apart from one another.

The first terminal portions 521 are individually disposed on the first conductor portions 511. The first terminal portions 521 are in contact with and cover the respective first end surfaces 511a of the first conductor portions 511.

The second terminal portion 522 is in contact with and covers the second end surface 512a of the second conductor portion 512.

The third terminal portions 523 are individually disposed on the third conductor portions 513. The third terminal portions 523 are in contact with and cover the respective third end surfaces 513a of the third conductor portions 513.

The sealing resin 6 is made of a synthetic resin mainly containing, for example, a black epoxy resin. The sealing resin 6 may contain a filler such as silica mixed into the epoxy resin. As shown in FIGS. 1, 2, 4, 6, and 7, the sealing resin 6 covers the first electronic component 1A, the second electronic component 1B, the columnar conductor 7, and the like. The sealing resin 6 also covers the bonding portions 31 and 32, a plurality of barrier metals 35, the wiring layer 4 and a part of the support member 2. The sealing resin 6 is formed on the support surface 21. The sealing resin 6 has a rectangular shape in plan view. The thickness (dimension along the thickness direction z) of the sealing resin 6 is not particularly limited, and is, for example, in a range from 200 μm to 1200 μm. As shown in FIGS. 1, 2, 4, 6, and 7, the sealing resin 6 includes a resin obverse surface 61, a resin reverse surface 62, and a plurality of resin side surfaces 63.

As shown in FIGS. 4, 6, and 7, the resin obverse surface 61 and the resin reverse surface 62 are spaced apart from each other in the thickness direction z. The resin obverse surface 61 and the resin reverse surface 62 face away from each other in the thickness direction z. The resin obverse surface 61 faces the same side in the thickness direction z as the element top surface 10a of the first electronic component 1A, the element top surface 10a of the second electronic component 1B, and the support surface 21. The resin reverse surface 62 faces the same side in the thickness direction z as the opposing surface 10b of the first electronic component 1A, the opposing surface 10b of the second electronic component 1B, and the reverse surface 22. The resin reverse surface 62 is in contact with the support surface 21. The resin reverse surface 62 has irregularities corresponding to the shape of the wiring layer 4. As shown in FIGS. 4, 6, and 7, in the thickness direction z, each of the resin side surfaces 63 is sandwiched between and connected to the resin obverse surface 61 and the resin reverse surface 62. As shown in FIGS. 1 and 2, the resin side surfaces 63 include one facing one side in the first direction x, one facing another side in the first direction x, one facing one side in the second direction y, and one facing another side in the second direction y. Each of the resin side surfaces 63 is flush with a corresponding one of the side surfaces 23.

The columnar conductor 7 is disposed in the side where the support surface 21 faces, with respect to the support member 2. The columnar conductor 7 is disposed on the second wiring portion 42 and extends upwardly in the thickness direction z from the second wiring portion 42. The columnar conductor 7 is electrically connected to the second conductor portion 512 and the second terminal portion 522 via the second wiring portion 42. The planar shape of the columnar conductor 7 is not particularly limited, and in the illustrated example, it is a band extending in the second direction y. In plan view, the columnar conductor 7 is disposed between the first electronic component 1A and the second electronic component 1B. The columnar conductor 7 contains, for example, metal such as copper. The columnar conductor 7 is formed, for example, by electroplating. In the present embodiment, the columnar conductor 7 is taller than the first electronic component 1A and the second electronic component 1B. The thickness (dimension along the thickness direction z) of the columnar conductor 7 is not particularly limited, and is, for example, in a range from 100 μm to 300 μm. As understood from FIGS. 2, 3, 5, and 6, in plan view, a pair of conductor end surfaces 72 extend in the second direction y from the first conductor portions 511 and the third conductor portions 513 or the first terminal portions 521 and the third terminal portions 523 arranged along one edge of the support member 2 in the second direction y, to the first conductor portions 511 and the third conductor portions 513 or the first terminal portions 521 and the third terminal portions 523 arranged along the other edge of the support member 2. The columnar conductor 7 includes a conductor top surface 71 and the pair of conductor end surfaces 72.

The conductor top surface 71 faces upward in the thickness direction z. The conductor top surface 71 faces the same side as the support surface 21 in the thickness direction z. The conductor top surface 71 also faces the same side as the element top surfaces 10a of the first electronic component 1A, the element top surfaces 10a of the second electronic component 1B, and the resin obverse surface 61. The conductor top surface 71 is covered with the sealing resin 6.

As shown in FIGS. 2 and 6, the pair of conductor end surfaces 72 are end surfaces of the columnar conductor 7 in the second direction y. One of the conductor end surfaces 72 faces one side in the second direction y, and the other faces another side in the second direction y. As shown in FIGS. 2 and 6, as viewed in the first direction x, the conductor end surfaces 72 are disposed in opposite sides of the first electronic component 1A, respectively, and outside of the first electronic component 1A. Also, as viewed in the first direction x, the conductor end surfaces 72 are disposed in opposite sides of the second electronic component 1B, respectively, and outside of the second electronic component 1B. The conductor end surfaces 72 are covered with the scaling resin 6.

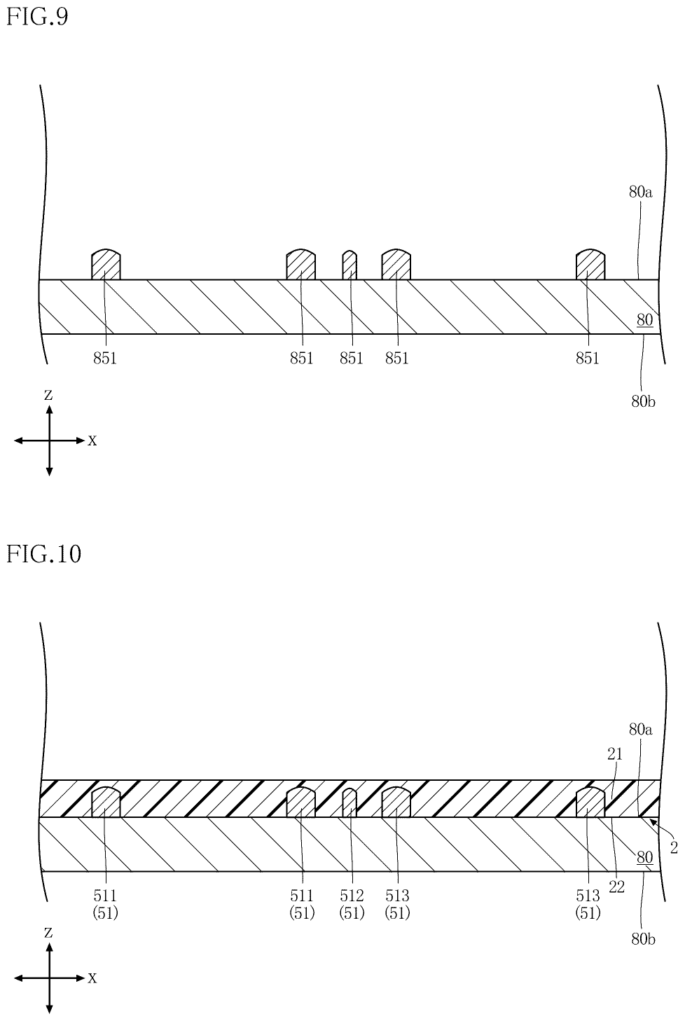

Next, an example of a method of manufacturing the electronic device A10 will be described with reference to FIGS. 9 to 18. FIGS. 9 to 18 are cross-sectional views each showing a step in the method of manufacturing the electronic device A10. These cross-sectional views each correspond to the sectional view shown in FIG. 7.

First, as shown in FIG. 9, a support substrate 80 is prepared, and a plurality of columnar bodies 851 are formed on the support substrate 80. The support substrate 80 contains, for example, an intrinsic single-crystal semiconductor material such as Si. In the step of preparing the support substrate 80, a silicon wafer may be prepared as the support substrate 80. The support substrate 80 includes a substrate obverse surface 80a and a substrate reverse surface 80b that face away from each other in the thickness direction z. The columnar bodies 851 are formed, for example, by the following steps. First, a seed layer is formed on the substrate obverse surface 80a, for example, by sputtering. Then, a resist is patterned on the seed layer, and the columnar bodies 851 are formed by electroplating. Thereafter, the resist and the unnecessary seed layer are removed. Through these steps, the columnar bodies 851 are formed on the substrate obverse surface 80a of the support substrate 80. The columnar bodies 851 will be formed into the through conductors 51.

Next, as shown in FIG. 10, the support member 2 is formed on the substrate obverse surface 80a of the support substrate 80 so as to cover the columnar bodies 851. The support member 2 is made of a synthetic resin mainly containing, for example, a black epoxy resin. The support member 2 may be formed by molding. The support member 2 may be made of an insulative resin material instead of the synthetic resin. The support member 2 includes the support surface 21 and the reverse surface 22 that face away from each other in the thickness direction z. The support surface 21 faces the same side as the substrate obverse surface 80a, and the reverse surface 22 faces the substrate obverse surface 80a. The support member 2 is formed so as to completely cover the columnar bodies 851.

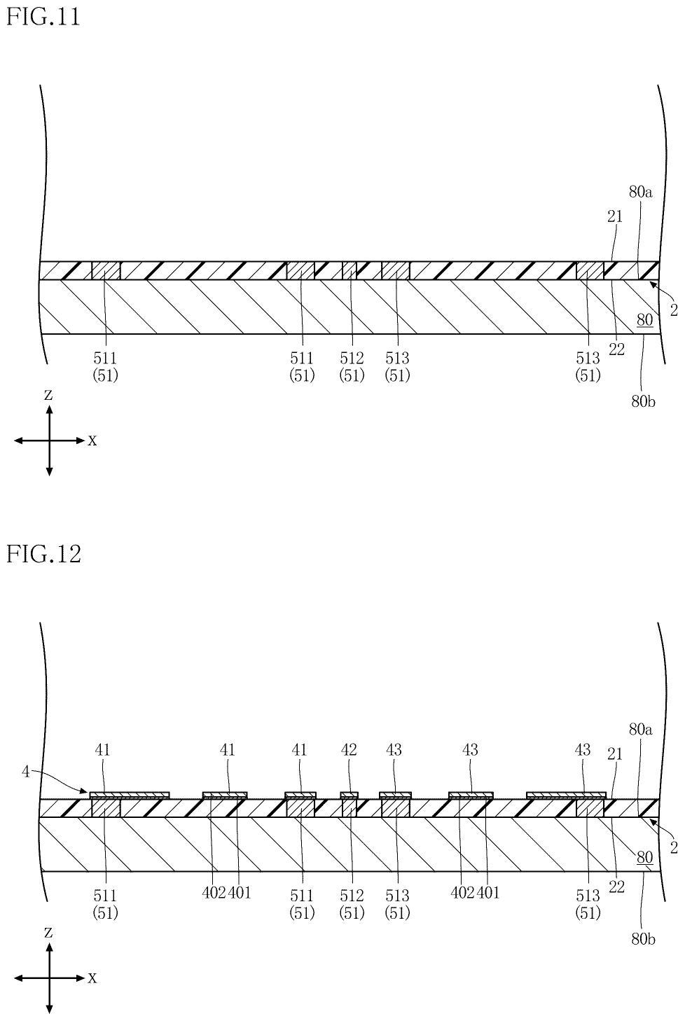

Next, as shown in FIG. 11, the support member 2 is ground so as to form the through conductors 51. In the state shown in FIG. 10, the support member 2 is ground downwardly from the support surface 21 in the thickness direction z until the columnar bodies 851 are exposed from the support surface 21. The grinding method is not particularly limited. The support member 2 may be thinned by a method other than grinding. As a result, the through conductors 51 are formed from the columnar bodies 851. The formed through conductors 51 include the first conductor portions 511, the second conductor portion 512, and the third conductor portions 513.

Next, as shown in FIG. 12, the wiring layer 4 is formed. The wiring layer 4 is formed, for example, by the following steps. First, a seed layer 401 is formed on the support surface 21 and on the through conductors 51. The seed layer 401 may be formed by sputtering. For example, the seed layer 401 is formed by sequentially laminating a Ti layer and a Cu layer. Next, a resist is patterned on the seed layer 401, and a plating layer 402 is formed by electroplating. The plating layer 402 contains, for example, copper. Thereafter, the resist and the unnecessary seed layer 401 (the portion of the seed layer 401 exposed from the plating layer 402) are removed. Through these steps, the wiring layer 4 is formed. The formed wiring layer 4 includes the first wiring portions 41, the second wiring portion 42, and the third wiring portions 43.

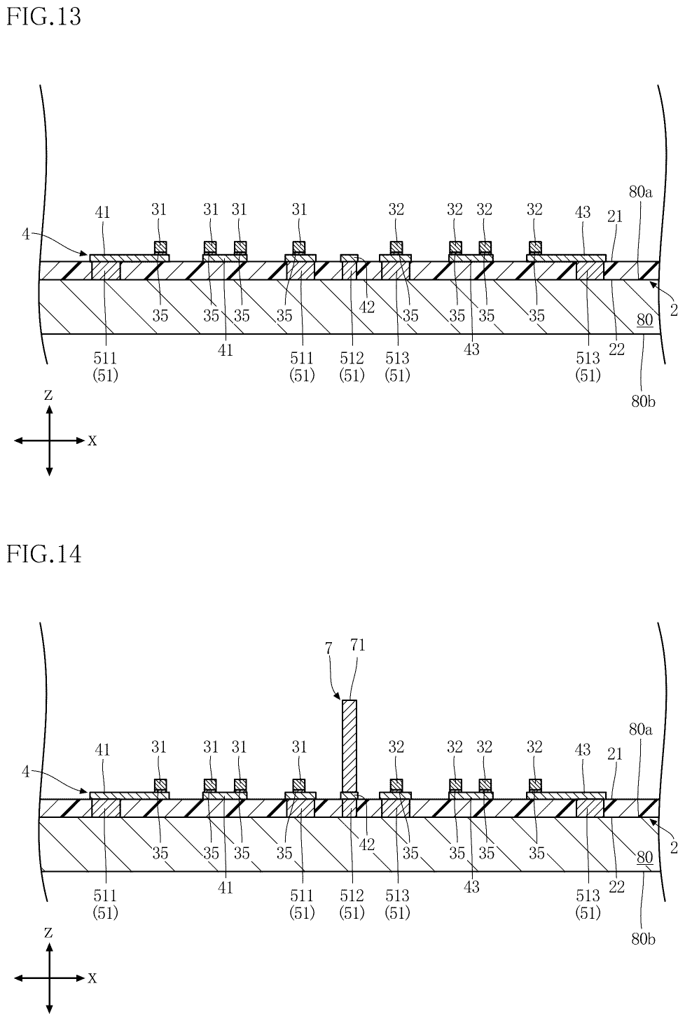

Next, as shown in FIG. 13, the barrier metals 35 and the bonding portions 31 and 32 are sequentially formed. Each barrier metal 35 contain metal different from that of the wiring layer 4 such as Ni. In the step of forming the bonding portions 31 and 32, solder pastes serving as the bonding portion 31 or 32 are formed on the respective barrier metals 35 by, for example, screen printing. The barrier metals 35 and the bonding portions 31 and 32 may be formed by electroplating, for example. In the electroplating, a seed layer for serving as an electrical conduction path may be newly formed, or the seed layer 401 formed in the step of forming the wiring layer 4 may be used without removal. The barrier metals 35 and the bonding portions 31 and 32 are respectively formed in regions where the first electronic component 1A and the second electronic component 1B will be bonded.

Next, as shown in FIG. 14, the columnar conductor 7 is formed. The columnar conductor 7 contains metal, such as copper. The columnar conductor 7 is formed by, for example, electroplating. In the electroplating, a seed layer for electrical conduction path may be newly formed, or the seed layer 401 formed in the step of forming the wiring layer 4 may be used without removal.

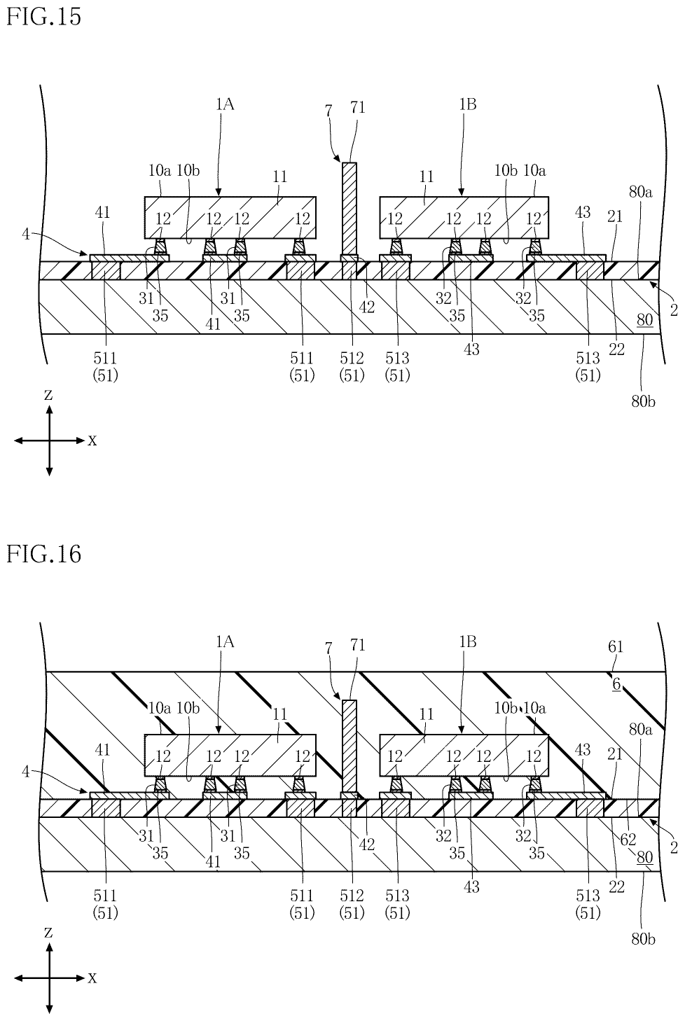

Next, as shown in FIG. 15, the first electronic component 1A and the second electronic component 1B are mounted and bonded. In the step of mounting the first electronic component 1A and the second electronic component 1B, as shown in FIG. 15, the electrode pads 12 of the first electronic component 1A are individually aligned with the bonding portions 31, and the electrode pads 12 of the second electronic component 1B are individually aligned with the bonding portions 32. Then, a reflow process is performed with the first electronic component 1A and the second electronic component 1B mounted. The heat generated during the reflow melts the bonding portions 31 and 32. Thereafter, the molten bonding portions 31 and 32 are cooled. As a result, the bonding portions 31 and 32 solidify, and the first electronic component 1A and the second electronic component 1B are bonded. As described above, the first electronic component 1A and the second electronic component 1B are flip-chip mounted with their opposing surfaces 10b facing the wiring layer 4.

Next, as shown in FIG. 16, the sealing resin 6 is formed. The sealing resin 6 is formed on the support member 2 so as to cover the first electronic component 1A, the second electronic component 1B, the wiring layer 4, and the columnar conductor 7. The sealing resin 6 may be formed by molding. The scaling resin 6 is made of a synthetic resin mainly containing, for example, a black epoxy resin. Alternatively, the sealing resin 6 may be made of an insulative resin material instead of the synthetic resin. The sealing resin 6 includes the resin obverse surface 61 that faces upward in the thickness direction z. In order to thin the sealing resin 6, the sealing resin 6 may be ground downwardly from the resin obverse surface 61 in the thickness direction z, as long as the columnar conductor 7 is not exposed.

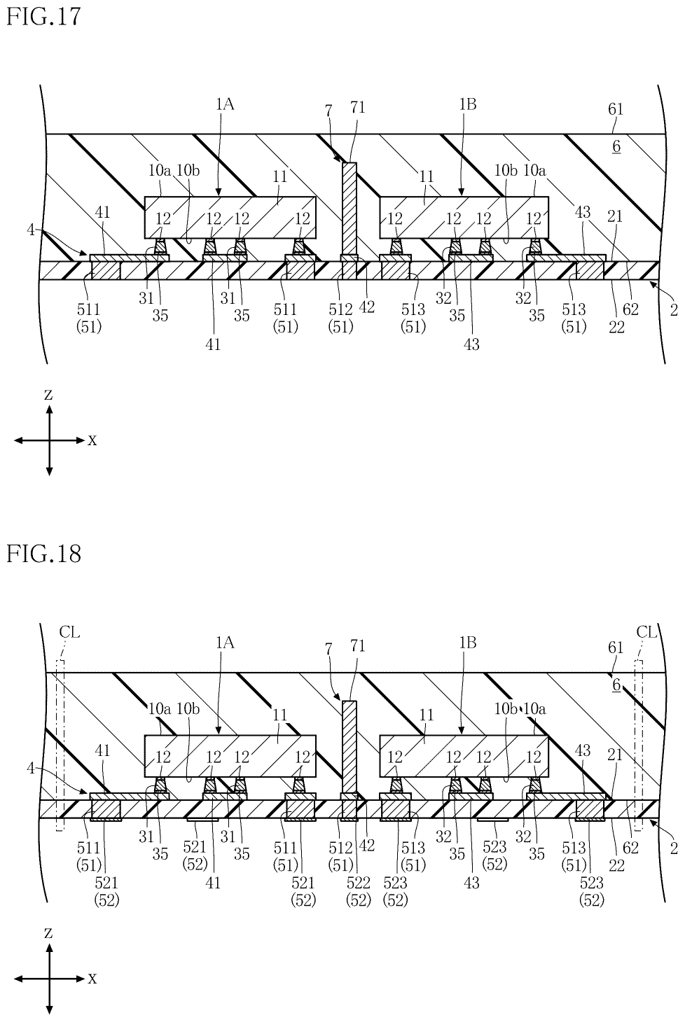

Next, as shown in FIG. 17, the support substrate 80 is removed. In the step of removing the support substrate 80, for example, the support substrate 80 is ground from side of the substrate reverse surface 80b in the state shown in FIG. 17. The grinding is performed from the substrate reverse surface 80b side. In the illustrated example, the grinding continues even after removal of the support substrate 80, thereby thinning the support member 2 and the through conductor 51 (each of the first conductor portions 511, the second conductor portion 512, and the third conductor portions 513). This thinning process may be omitted.

Next, as shown in FIG. 18, the terminal 52 is formed. The terminal 52 is formed on the surface of the through conductor 51 that is exposed from the reverse surface 22. The terminal 52 may be formed by electroless plating. In the electroless plating, a Ni layer, a Pd layer, and an Au layer are laminated in this order on the through conductor 51. The formed terminal 52 includes the first terminal portions 521, the second terminal portion 522, and the third terminal portions 523.

Next, the sealing resin 6 and the support member 2 are cut along the cutting line CL shown in FIG. 18, to separate into individual pieces. The cutting of the sealing resin 6 and the support member 2 may be performed by a cutting process with a dicing blade. As a result, the sealing resin 6 and the support member 2 are divided along the cutting line CL.

Through the above-described steps, the electronic device A10 shown in FIGS. 1 to 8 is manufactured. Note that the method of manufacturing the electronic device A10 is not limited to the described example. For example, when the support member 2 contains an intrinsic single-crystal semiconductor (such as Si), the device may be manufactured as follows. First, grooves are formed on the support substrate 80 (silicon wafer) by etching or the like. Then, the columnar bodies 851 (through conductor 51) are formed in the grooves. Thereafter, without forming the support member 2 (resin layer), the wiring layer 4 is formed. In addition, after forming the sealing resin 6, the support substrate 80 may be ground, instead of being removed, until the columnar bodies 851 (through conductor 51) formed in the grooves are exposed. By modifying the process in this way, the electronic device A10 including the support member 2 made of a semiconductor material may be manufactured.

The operative effects of the electronic device A10 will be described.

The electronic device A10 includes the first electronic component 1A, the support member 2, and the columnar conductor 7. The support member 2 includes the support surface 21 supporting the first electronic component 1A. The columnar conductor 7 is disposed on the support surface 21 (i.e., in a direction where the support surface 21 faces with respect to the support member 2). With such a configuration, the columnar conductor 7 functions as an electromagnetic shield. Hence, the first electronic component 1A can be prevented from being exposed to external electromagnetic noise. Therefore, the electronic device A10 is advantageous for improving operational reliability.

In the electronic device A10, the columnar conductor 7 is disposed between the first electronic component 1A and the second electronic component 1B. Such a configuration can suppress the propagation of electromagnetic noise (radiated noise) generated from the second electronic component 1B to the first electronic component 1A, and the propagation of electromagnetic noise (radiated noise) generated from the first electronic component 1A to the second electronic component 1B. In other words, mutual electromagnetic interference between the first electronic component 1A and the second electronic component 1B can be suppressed. Hence, the electronic device A10 is advantageous for improving operational reliability.

The electronic device A10 includes the columnar conductor 7 disposed between the first wiring portions 41 and the third wiring portions 43. The first wiring portions 41 are electrically connected to the first electronic component 1A, and the third wiring portions 43 are electrically connected to the second electronic component 1B. The first wiring portions 41 transmit input signals to the first electronic component 1A and output signals from the first electronic component 1A. Similarly, the third wiring portions 43 transmit input signals to the second electronic component 1B and output signals from the second electronic component 1B. Thus, the first wiring portions 41 and the third wiring portions 43 may emitted or receive electromagnetic noise. Therefore, the arrangement of the columnar conductor 7 between the first wiring portions 41 and the third wiring portions 43 can suppress mutual electromagnetic interference between an electric circuit including the first electronic component 1A and the first wiring portions 41 and an electric circuit including the second electronic component 1B and the third wiring portions 43. Hence, the electronic device A10 is advantageous for improving operational reliability.

In the electronic device A10, the conductor top surface 71 of the columnar conductor 7 is located between the element top surface 10a of the first electronic component 1A and the resin obverse surface 61 in the thickness direction z. In this configuration, the columnar conductor 7 extends to an upper position than the first electronic component 1A. This enhances the effect of suppressing the intrusion of electromagnetic noise (e.g., radiated noise from the second electronic component 1B) into the first electronic component 1A. Furthermore, in the electronic device A10, the conductor top surface 71 of the columnar conductor 7 is located between the element top surface 10a of the second electronic component 1B and the resin obverse surface 61 in the thickness direction z. In this configuration, the columnar conductor 7 extends to an upper position than the first electronic component 1A and the second electronic component 1B. This can suppress electromagnetic noise from propagating over the columnar conductor 7 from the first electronic component 1A to the second electronic component 1B, or vice versa. Thus, the mutual electromagnetic interference between the first electronic component 1A and the second electronic component 1B can be more effectively suppressed. Accordingly, the electronic device A10 is more advantageous for improving operational reliability.

In the electronic device A10, the pair of conductor end surfaces 72 of the columnar conductor 7 are located outside of the first electronic component 1A in the second direction y. In this configuration, the columnar conductor 7 extends in the second direction y beyond the outer edges of the first electronic component 1A. This enhances the effect of suppressing the intrusion of electromagnetic noise (e.g., radiated noise from the second electronic component 1B) into the first electronic component 1A. Furthermore, in the electronic device A10, the pair of conductor end surfaces 72 of the columnar conductor 7 are located outside of the second electronic component 1B in the second direction y. In this configuration, the columnar conductor 7 extends in the second direction y beyond the outer edges of the second electronic component 1B. This can suppress electromagnetic noise from propagating around the columnar conductor 7 from the first electronic component 1A to the second electronic component 1B, or vice versa. Thus, the mutual electromagnetic interference between the first electronic component 1A and the second electronic component 1B can be more effectively suppressed. Accordingly, the electronic device A10 is more advantageous for improving operational reliability.

The electronic device A10 includes the second conductor portion 512 and the second terminal portion 522. The second terminal portion 522 is exposed outside the electronic device A10 and is electrically connected to the columnar conductor 7. With such a configuration, when the electronic device A10 is mounted on a circuit board, the columnar conductor 7 can be grounded via the second terminal portion 522. As a result, the electromagnetic shielding effect provided by the columnar conductor 7 can be further enhanced in the electronic device A10.

Other embodiments and variations of electronic devices of the present disclosure will be described below. Various parts of embodiments and variations may be selectively used in any appropriate combination as long as it is technically compatible.

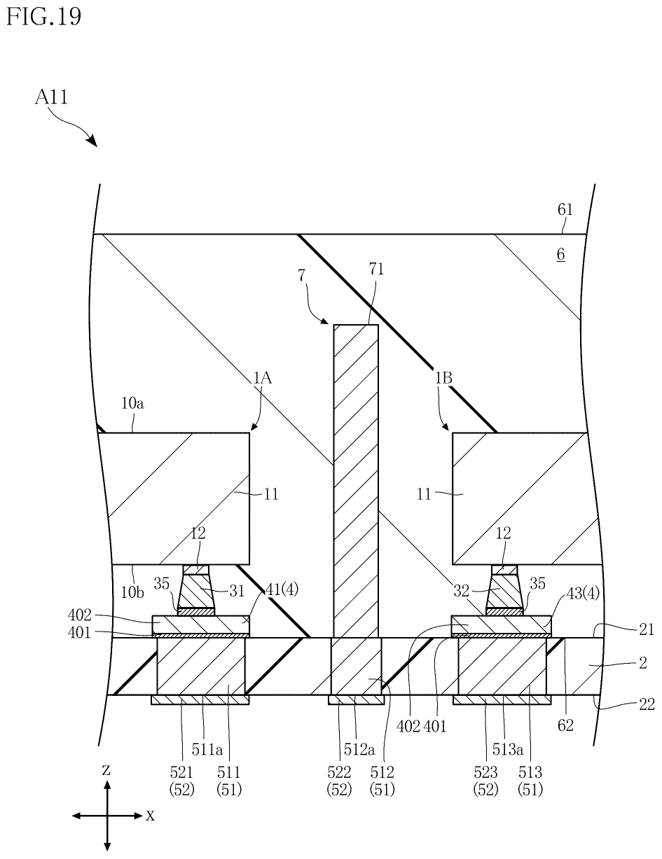

FIG. 19 shows an electronic device A11 according to a first variation of the first embodiment. The electronic device A11 differs from the electronic device A10 in the following points. The wiring layer 4 of the electronic device A11 does not include the second wiring portion 42. In the electronic device A11, the columnar conductor 7 is directly formed on the first conductor portion 511 and is in contact with the upper surface of the first conductor portion 511.

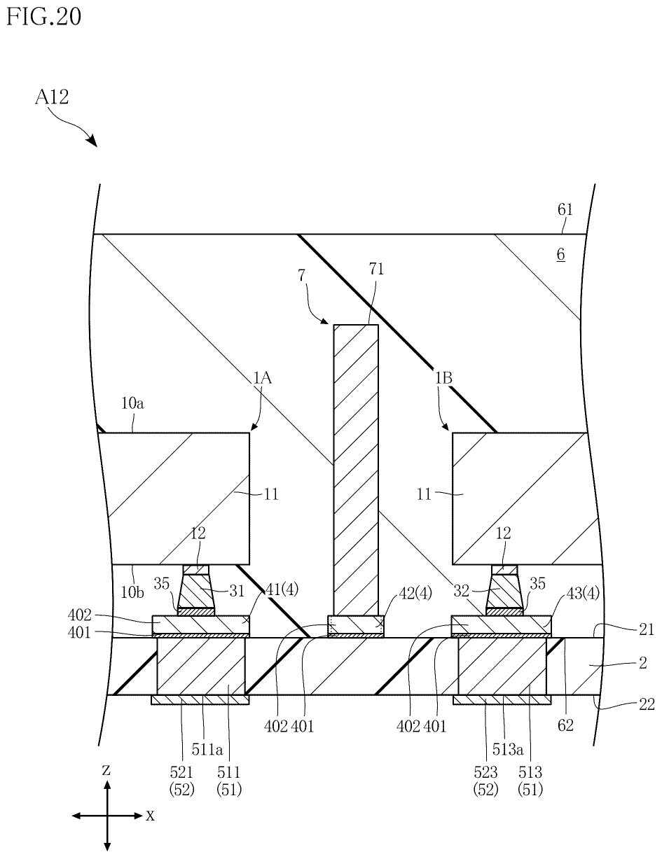

FIG. 20 shows an electronic device A12 according to a second variation of the first embodiment. The electronic device A12 differs from the electronic device A10 in the following points. The through conductor 51 does not include the second conductor portion 512, and the terminal 52 does not include the second terminal portion 522. In the electronic device A12, the second wiring portion 42 of the wiring layer 4 is formed directly on the support surface 21 of the support member 2 and is in contact with the support surface 21.

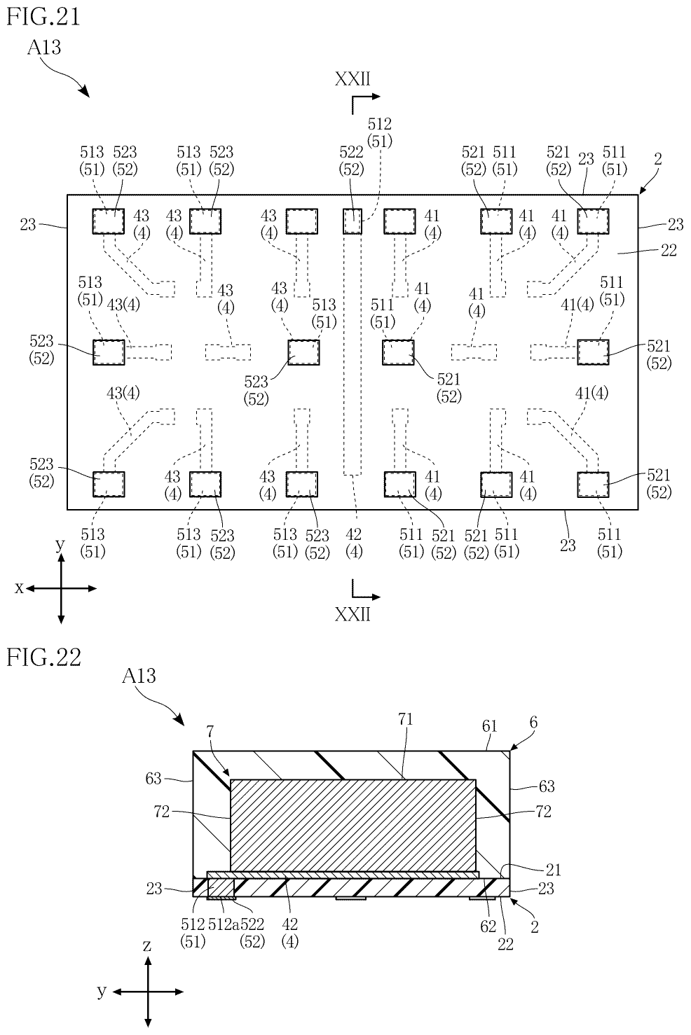

FIGS. 21 and 22 show an electronic device A13 according to a third variation of the first embodiment. The electronic device A13 differs from the electronic device A10 in the following points. The second conductor portion 512 and the second terminal portion 522 are formed in different regions. In the electronic device A10, the second conductor portion 512 and the second terminal portion 522 are each formed on the substantially entire region below the second wiring portion 42 in the thickness direction z. In contrast, in the electronic device A13, they are formed only in a part of the region below the second wiring portion 42 in the thickness direction z. As understood from the present variation, in the electronic device according to the present disclosure, the positions of the second conductor portion 512 and the second terminal portion 522 as viewed in the thickness direction z can be appropriately modified depending on the range of the second wiring portion 42, and they are not limited to the region below the columnar conductor 7.

In each of the electronic devices A11 to A13 according to these variations, the columnar conductor 7 serves as an electromagnetic shield, as with the electronic device A10. Accordingly, the electronic devices A11 to A13 are advantageous for improving operational reliability, as with the electronic device A10. In addition, the electronic devices A11 to A13 may have a configuration in common with the electronic device A10, thereby achieving the same effect as the electronic device A10.

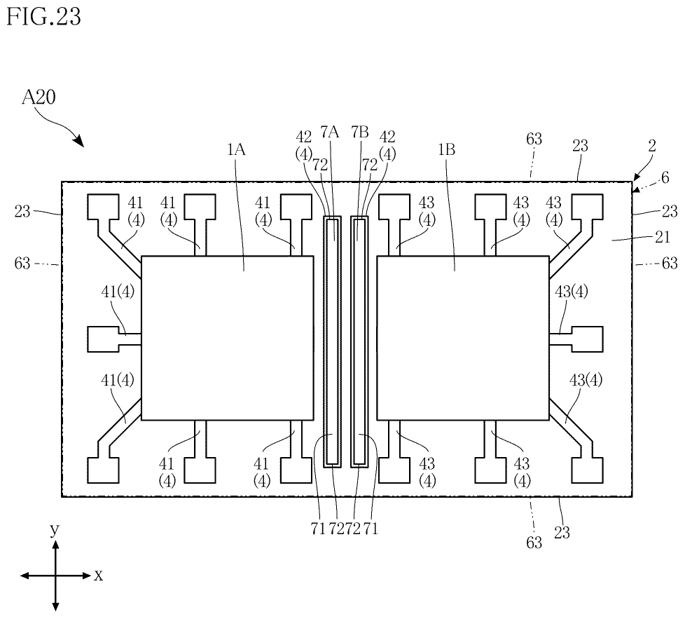

FIG. 23 shows an electronic device A20 according to a second embodiment. The electronic device A20 differs from the electronic device A10 in that it includes two columnar conductors 7.

The electronic device A20 includes two columnar conductors 7, which are referred to as a first columnar conductor 7A and a second columnar conductor 7B. The first columnar conductor 7A and the second columnar conductor 7B each have a band-like shape extending in the second direction y in plan view. The first columnar conductor 7A and the second columnar conductor 7B are spaced apart from each other in the first direction x and are parallel to each other. Each of the first columnar conductor 7A and the second columnar conductor 7B is disposed between the first electronic component 1A and the second electronic component 1B.

In the electronic device A20, the wiring layer 4 includes two second wiring portions 42. The first columnar conductor 7A is formed on one of the second wiring portions 42, and the second columnar conductor 7B is formed on the other of the second wiring portions 42. Below each second wiring portion 42 in the thickness direction z, the second conductor portion 512 and the second terminal portion 522 are formed, respectively.

In the electronic device A20, each of the first columnar conductor 7A and the second columnar conductor 7B functions as an electromagnetic shield. Accordingly, the electronic device A20 is advantageous for improving operational reliability, as with the electronic device A10. In addition, the electronic device A20 may have a configuration in common with the electronic devices A10 to A13, thereby achieving the same effect as the electronic devices A10 to A13.

The electronic device A20 includes the first columnar conductor 7A and the second columnar conductor 7B. Accordingly, the mutual electromagnetic interference between the first electronic component 1A and the second electronic component 1B can be more effectively suppressed.

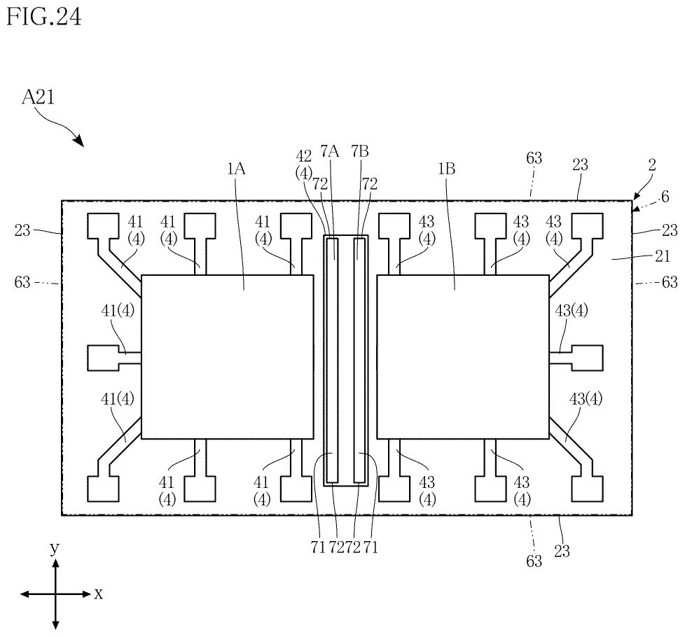

FIG. 24 shows an electronic device A21 according to a variation of the second embodiment. The electronic device A21 differs from the electronic device A20 in the following points. The first columnar conductor 7A and the second columnar conductor 7B are both formed on a single second wiring portion 42. As understood from the present variation, in the electronic device according to the present disclosure, the first columnar conductor 7A and the second columnar conductor 7B may be formed on two different second wiring portions 42, or may be formed on a common second wiring portion 42.

In the electronic device A21, each of the first columnar conductor 7A and the second columnar conductor 7B functions as an electromagnetic shield, as with the electronic device A20. Accordingly, the electronic device A21 is advantageous for improving operational reliability, as with the electronic device A20. In addition, the electronic device A21 may have a configuration in common with the electronic devices A10 to A13 and A20, thereby achieving the same effect as the electronic devices A10 to A13 and A20.

As the second embodiment (including its variation), an example is described in which the two columnar conductors 7 (the first columnar conductor 7A and the second columnar conductor 7B) are provided. However, the number of columnar conductors 7 is not limited to two and may be three or more.

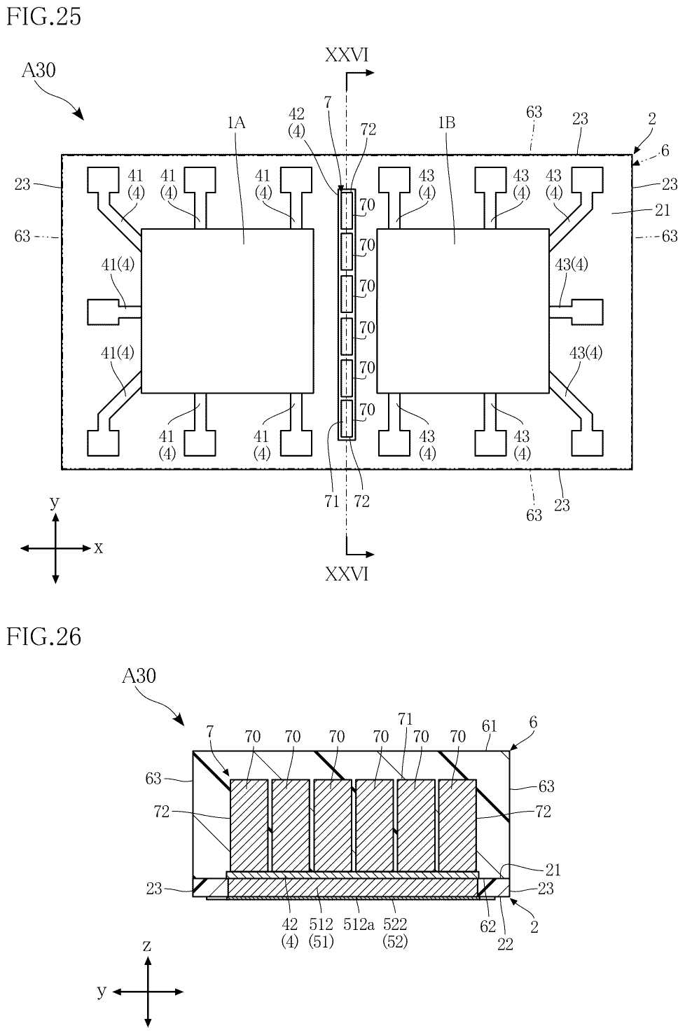

FIGS. 25 and 26 show an electronic device A30 according to a third embodiment. The electronic device A30 differs from the electronic device A10 in that the columnar conductor 7 includes a plurality of separated portions 70.

The separated portions 70 are arranged along the second direction y and are spaced apart from one another. In the present embodiment, the conductor top surface 71 corresponds to the upper surfaces (surfaces facing upward in the thickness direction z) of the separated portions 70. The pair of conductor end surfaces 72 corresponds to the surface of the separated portion 70 located at one end in the second direction y and the surface of the separated portion 70 located at the opposite end in the second direction y. The spacing between the separated portions 70 is not particularly limited, and is, for example, in a range from 30 μm to 50 μm.

In the electronic device A30, the columnar conductor 7 (the separated portions 70) functions as an electromagnetic shield, as with the electronic device A10. Accordingly, the electronic device A30 is advantageous for improving operational reliability, as with the electronic device A10. In addition, the electronic device A30 may have a configuration in common with the electronic devices A11 to A13, A20 and A21, thereby achieving the same effect as the electronic devices A11 to A13, A20 and A21. As understood from the present embodiment, in the electronic device according to the present disclosure, the columnar conductor 7 is not limited to a continuous structure extending from one of the pair of conductor end surfaces 72 to the other, but may alternatively be divided into a plurality of portions. In the electronic device A30, the spacing between the separated portions 70 is, for example, in a range from 30 μm to 50 μm. Such a configuration allows the sealing resin 6 to be filled between the separated portions 70, while adequately maintaining the electromagnetic shielding effect.

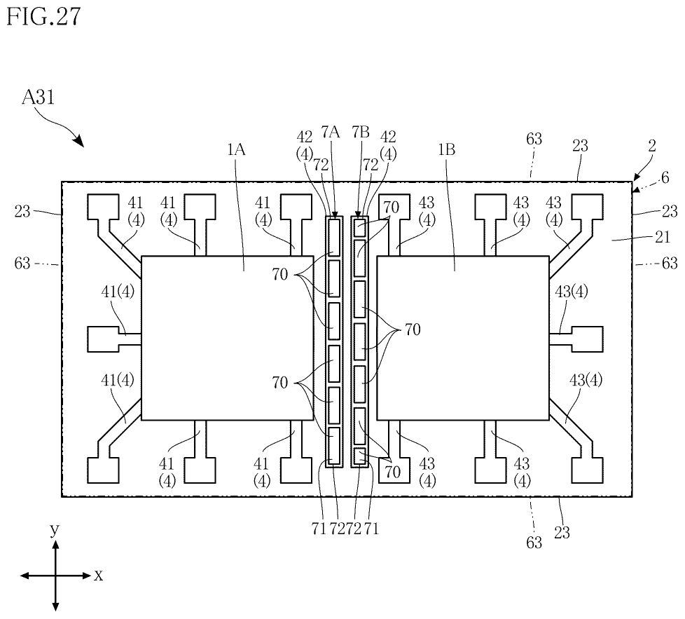

FIG. 27 shows an electronic device A31 according to a variation of the third embodiment. The electronic device A31 differs from the electronic device A30 in the following points. The electronic device A31 includes the first columnar conductor 7A and the second columnar conductor 7B, and each of them includes a plurality of separated portions 70. In the illustrated example, gaps between the separated portions 70 of the first columnar conductor 7A and gaps of the second columnar conductor 7B are arranged in a staggered manner in the second direction y. In other words, as viewed in the first direction x, the gaps between the separated portions 70 of the first columnar conductor 7A overlaps with the respective separated portions 70 of the second columnar conductor 7B. Alternatively, the gaps between the separated portions 70 of the first columnar conductor 7A and the gaps of the second columnar conductor 7B may be aligned in the second direction y. In other words, as viewed in the first direction x, the gaps between the separated portions 70 of the first columnar conductor 7A overlaps with the respective gaps between the separated portions 70 of the second columnar conductor 7B. In the example shown in FIG. 27, the first columnar conductor 7A and the second columnar conductor 7B are formed on the respective second wiring portions 42, as with the electronic device A20. However, as with the electronic device A21, they may instead be formed on a single second wiring portion 42 (a common second wiring portion 42).

In the electronic device A31, the columnar conductor 7 (the separated portions 70) functions as an electromagnetic shield, as with the electronic device A30. Accordingly, the electronic device A31 is advantageous for improving operational reliability, as with the electronic device A30. In addition, the electronic device A31 may have a configuration in common with the electronic devices A10 to A13, A20, A21 and A30, thereby achieving the same effect as the electronic devices A10 to A13, A20, A21 and A30.

In the electronic device A31, the gaps between the separated portions 70 of the first columnar conductor 7A and the gaps of the second columnar conductor 7B are arranged in a staggered manner in the second direction y. With such a configuration, even when electromagnetic noise passes through the gaps in the separated portions 70 of the first columnar conductor 7A, the second columnar conductor 7B serves as a barrier to the electromagnetic noise (and vice versa). Accordingly, the electronic device A31 can more effectively suppress mutual electromagnetic interference between the first electronic component 1A and the second electronic component 1B, compared to the electronic device A30.

As the third embodiment (including its variation), the separated portions 70 are formed on the single second wiring portion 42 (the common second wiring portion 42). However, the wiring layer 4 may alternatively include a plurality of second wiring portions 42, and the separated portions 70 may be individually formed on the respective second wiring portions 42.

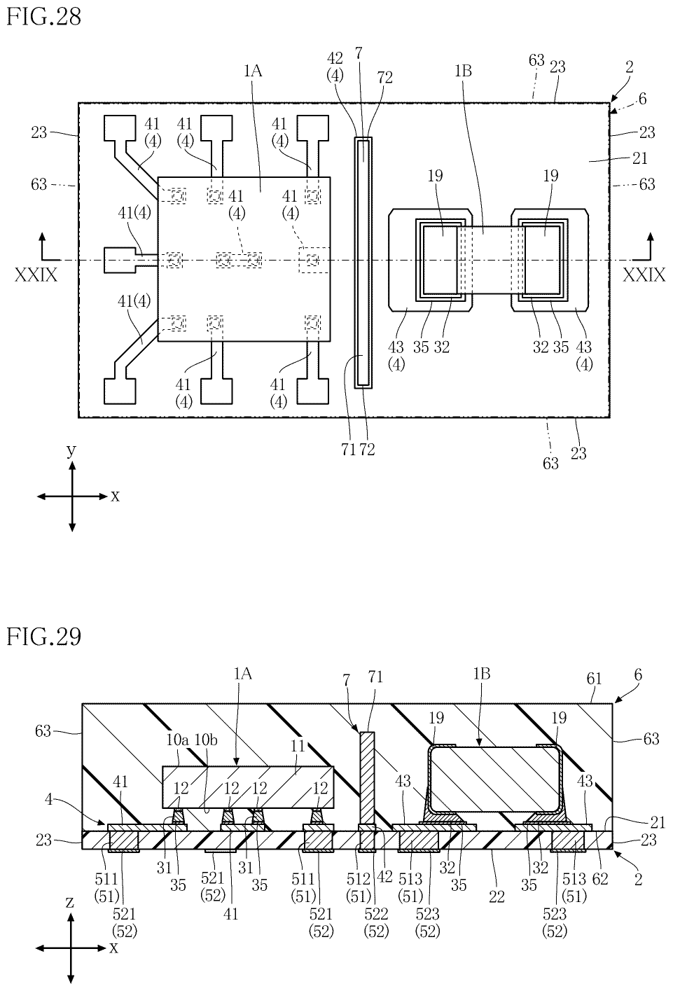

The first to third embodiments described above (including their variations) are examples where each of the first electronic component 1A and the second electronic component 1B is a flip-chip mounted device (e.g., an LSI). Alternatively, one or both of these components may be a surface-mount device (SMD). FIGS. 28 and 29 show an electronic device in which the first electronic component 1A is an LSI and the second electronic component 1B is an SMD.

In the electronic device shown in FIGS. 28 and 29, the second electronic component 1B is, for example, either a resistor, a capacitor, an inductor, or a diode. The second electronic component 1B includes a pair of terminals 19. The pair of terminals 19 are disposed at opposite ends of the second electronic component 1B in the first direction x, respectively. Alternatively, the pair of terminals 19 may be disposed at opposite ends of the second electronic component 1B in the second direction y, respectively. As shown in FIG. 29, each terminal 19 is bonded to the barrier metal 35 on the third wiring portion 43 via the bonding portion 32. As shown in FIG. 29, a fillet is formed on each bonding portion 32.

As understood from the example shown in FIGS. 28 and 29, in the electronic device according to the present disclosure, whether each of the first electronic component 1A and the second electronic component 1B is mounted by flip-chip bonding or is a surface mount device (SMD) is not particularly limited.

The first to third embodiments described above (including their variations) are described as examples where the thickness of the columnar conductor 7 (the first columnar conductor 7A and the second columnar conductor 7B) is greater than the thickness of each of the first electronic component 1A and the second electronic component 1B. However, the thickness of the columnar conductor 7 may alternatively be smaller than the thickness of the first electronic component 1A or the thickness of the second electronic component 1B. Further, examples are described where the width of the columnar conductor 7 (dimension along the second direction y) is greater than the width (dimension along the second direction y) of each of the first electronic component 1A and the second electronic component 1B. However, the width of the columnar conductor 7 may alternatively be smaller than the width of the first electronic component 1A or the width of the second electronic component 1B.

The electronic devices according to the present disclosure are not limited to the embodiments described above. The specific configuration of each part of the electronic device of the present disclosure may suitably be designed and changed in various manners. For example, the present disclosure includes the embodiments described in the following clauses.

### Clause 1.

An electronic device comprising:
a first electronic component;
a support member including a support surface supporting the first electronic component;
a columnar conductor disposed in a direction where the support surface faces with respect to the support member; and
a sealing resin formed on the support surface and covering the first electronic component,
wherein the columnar conductor includes a conductor top surface facing the same side as the support surface in a thickness direction of the support member, and
the conductor top surface is covered with the sealing resin.

### Clause 2.

The electronic device according to clause 1, further comprising a second electronic component,
wherein the first electronic component and the second electronic component are arranged along a first direction orthogonal to the thickness direction, and
the columnar conductor is disposed between the first electronic component and the second electronic component, as viewed in the thickness direction.

### Clause 3.

The electronic device according to clause 2, wherein the first electronic component includes a first element top surface facing the same side as the conductor top surface in the thickness direction,
the second electronic component includes a second element top surface facing the same side as the conductor top surface in the thickness direction,
the sealing resin includes a resin obverse surface facing the same side as the conductor top surface in the thickness direction, and
in the thickness direction, the conductor top surface is located between the first element top surface and the resin obverse surface, and between the second element top surface and the resin obverse surface.

### Clause 4.

The electronic device according to clause 2 or 3, wherein the columnar conductor has two ends in a second direction orthogonal to the thickness direction and the first direction, the two ends disposed outside of the first electronic component and outside of the second electronic component.

### Clause 5.

The electronic device according to any one of clauses 2 to 4, wherein the columnar conductor includes a plurality of separated portions spaced apart from each other, and the plurality of separated portions are arrayed along a second direction orthogonal to the thickness direction and the first direction, as viewed in the thickness direction.

### Clause 6.

The electronic device according to any one of clauses 2 to 4, further comprising a second columnar conductor, the columnar conductor being referred to as a first columnar conductor,
the first columnar conductor and the second columnar conductor are arranged along the first direction, and
each of the first columnar conductor and the second columnar conductor extends along a second direction orthogonal to the thickness direction and the first direction, as viewed in the thickness direction.

### Clause 7.

The electronic device according to any one of clauses 1 to 6, further comprising a wiring layer interposed between the support member and the sealing resin.

### Clause 8.

The electronic device according to clause 7, further comprising a conductive bonding portion,
wherein the first electronic component includes an opposing surface facing the wiring layer in the thickness direction, and at least one electrode pad disposed on the opposing surface, and
the bonding portion is interposed between the at least one electrode pad and the wiring layer.

### Clause 9.

The electronic device according to clause 7 or 8, wherein the wiring layer includes a seed layer in contact with the support member, and a plating layer laminated on the seed layer, and
the columnar conductor is made of the same material as the plating layer.

### Clause 10.

The electronic device according to clause 9, wherein the plating layer and the columnar conductor contain copper.

### Clause 11.

The electronic device according to any one of clauses 7 to 10, further comprising a through conductor penetrating the support member in the thickness direction,
wherein the wiring layer includes a first wiring portion electrically connected to the first electronic component.

### Clause 12.

The electronic device according to clause 11, further comprising a first terminal portion,
wherein the through conductor includes a first conductor portion electrically connected to the first electronic component through the first wiring portion,
the first conductor portion includes a first end surface facing away from the sealing resin in the thickness direction,
the first end surface is exposed from the support member, and
the first terminal portion covers the first end surface.

### Clause 13.

The electronic device according to clause 12, wherein the through conductor includes a second conductor portion electrically connected to the columnar conductor.

### Clause 14.

The electronic device according to clause 13, wherein the wiring layer includes a second wiring portion interposed between the columnar conductor and the second conductor portion.

### Clause 15.

The electronic device according to clause 13 or 14, wherein the second conductor portion includes a second end surface facing away from the sealing resin in the thickness direction, and
the second end surface is exposed from the support member.

### Clause 16.

The electronic device according to clause 15, further comprising a second terminal portion
the second terminal portion covers the second end surface.

### REFERENCE NUMERALS

A10, A11, A12, A13, A20, A21, A30, A31: Electronic device, 1A: First electronic component, 1B: Second electronic component, 10a: Element top surface, 10b: Opposing surface, 11: Body portion, 12: Electrode pad, 19: Terminal, 2: Support member, 21: Support surface, 22: Reverse surface, 23: Side surface, 31: Bonding portion, 32: Bonding portion, 35: Barrier metal, 4: Wiring layer, 401: Seed layer, 402: Plating layer, 41: First wiring portion, 42: Second wiring portion, 43: Third wiring portion, 51: Through conductor, 511: First conductor portion, 511a: First end surface, 512: Second conductor portion, 512a:

Second end surface, 513: Third conductor portion, 513a: Third end surface, 52: Terminal, 521: First terminal portion, 522: Second terminal portion, 523: Third terminal portion, 6: Sealing resin, 61: Resin obverse surface, 62: Resin reverse surface, 63: Resin side surface, 7: Columnar conductor, 7A: First columnar conductor, 7B: Second columnar conductor, 70: Separated portion, 71: Conductor top surface, 72: Conductor end surface, 80: Support substrate, 80a: Substrate obverse surface, 80b: Substrate reverse surface, 851: Columnar body, CL: Cutting line

1. An electronic device comprising:
a first electronic component;
a support member including a support surface supporting the first electronic component;
a columnar conductor disposed in a direction where the support surface faces with respect to the support member; and
a sealing resin formed on the support surface and covering the first electronic component,
wherein the columnar conductor includes a conductor top surface facing the same side as the support surface in a thickness direction of the support member, and
the conductor top surface is covered with the sealing resin.

2. The electronic device according to claim 1, further comprising a second electronic component,
wherein the first electronic component and the second electronic component are arranged along a first direction orthogonal to the thickness direction, and
the columnar conductor is disposed between the first electronic component and the second electronic component, as viewed in the thickness direction.

3. The electronic device according to claim 2, wherein the first electronic component includes a first element top surface facing the same side as the conductor top surface in the thickness direction,
the second electronic component includes a second element top surface facing the same side as the conductor top surface in the thickness direction,
the sealing resin includes a resin obverse surface facing the same side as the conductor top surface in the thickness direction, and
in the thickness direction, the conductor top surface is located between the first element top surface and the resin obverse surface, and between the second element top surface and the resin obverse surface.

4. The electronic device according to claim 2, wherein the columnar conductor has two ends in a second direction orthogonal to the thickness direction and the first direction, the two ends disposed outside of the first electronic component and outside of the second electronic component.

5. The electronic device according to claim 2, wherein the columnar conductor includes a plurality of separated portions spaced apart from each other, and
the plurality of separated portions are arrayed along a second direction orthogonal to the thickness direction and the first direction, as viewed in the thickness direction.

6. The electronic device according to claim 2, further comprising a second columnar conductor, the columnar conductor being referred to as a first columnar conductor,
the first columnar conductor and the second columnar conductor are arranged along the first direction, and
each of the first columnar conductor and the second columnar conductor extends along a second direction orthogonal to the thickness direction and the first direction, as viewed in the thickness direction.

7. The electronic device according to claim 1, further comprising a wiring layer interposed between the support member and the sealing resin.

8. The electronic device according to claim 7, further comprising a conductive bonding portion,
wherein the first electronic component includes an opposing surface facing the wiring layer in the thickness direction, and at least one electrode pad disposed on the opposing surface, and
the bonding portion is interposed between the at least one electrode pad and the wiring layer.

9. The electronic device according to claim 7, wherein the wiring layer includes a seed layer in contact with the support member, and a plating layer laminated on the seed layer, and
the columnar conductor is made of the same material as the plating layer.

10. The electronic device according to claim 9, wherein the plating layer and the columnar conductor contain copper.

11. The electronic device according to claim 7, further comprising a through conductor penetrating the support member in the thickness direction,
wherein the wiring layer includes a first wiring portion electrically connected to the first electronic component.

12. The electronic device according to claim 11, further comprising a first terminal portion,
wherein the through conductor includes a first conductor portion electrically connected to the first electronic component through the first wiring portion,
the first conductor portion includes a first end surface facing away from the sealing resin in the thickness direction,
the first end surface is exposed from the support member, and
the first terminal portion covers the first end surface.

13. The electronic device according to claim 12, wherein the through conductor includes a second conductor portion electrically connected to the columnar conductor.

14. The electronic device according to claim 13, wherein the wiring layer includes a second wiring portion interposed between the columnar conductor and the second conductor portion.

15. The electronic device according to claim 13, wherein the second conductor portion includes a second end surface facing away from the sealing resin in the thickness direction, and
the second end surface is exposed from the support member.

16. The electronic device according to claim 15, further comprising a second terminal portion
the second terminal portion covers the second end surface.
